(19) United States
(12) Patent Application Publication
(10) Pub. No.: US 2026/0080123 A1
(43) Pub. Date: Mar. 19, 2026

(54) RECORDING MEDIUM, INFORMATION PROCESSING METHOD, AND INFORMATION PROCESSING DEVICE

(71) Applicant: Fujitsu Limited, Kawasaki-shi (JP)

(72) Inventors: Satoshi IMAMURA, Kawasaki (JP); Keiji KIMURA, Kawasaki (JP)

(73) Assignee: Fujitsu Limited, Kawasaki-shi (JP)

(21) Appl. No.: 19/328,555

(22) Filed: Sep. 15, 2025

(30) Foreign Application Priority Data
Sep. 18, 2024 (JP) 2024-161012

(51) Int. Cl. G06F 30/25

(52) U.S. Cl. CPC G06F 30/25

(57) ABSTRACT

A recording medium stores therein an information processing program for causing a computer to execute a process including: obtaining a fragment count by which a structure of a molecule-under-analysis containing multiple atoms is divided, information specifying an orbital count for and coordinates of each of the atoms; based on the obtained information and coordinates, executing: assigning among the atoms, two or more atoms, a number thereof being equal to the obtained fragment count, the two or more atoms being assigned in descending order of the orbital count, respectively, to two or more fragments, a number thereof being equal to the obtained fragment count; assigning, with respect to each of the two or more fragments, an atom that of remaining atoms exclusive of the two or more atoms, is close in distance to another atom already assigned to the each of the two or more fragments; assigning the atoms to the two or more fragments; and outputting the two or more fragments to which the atoms are assigned.

### CROSS REFERENCE TO RELATED APPLICATIONS

This application is based upon and claims the benefit of priority of the prior Japanese Patent Application No. 2024-161012, filed on Sep. 18, 2024, the entire contents of which are incorporated herein by reference.

### FIELD

Embodiments discussed herein relate to a recording medium, an information processing method, and an information processing device.

### BACKGROUND

Conventionally, in the fields of drug development or material development, there is a quantum chemical calculation technique for analyzing the structure or properties of a molecule that is a candidate for a drug or material. In quantum chemical calculation, for example, the ground-state energy or excitation energy of a molecule is calculated. Here, in order to reduce the amount of processing in the quantum chemical calculation, there is a density matrix embedding theory in which the structure of a molecule is divided into multiple fragments previous to calculating the ground-state energy.

As an example of a prior art, there is a technique in which each atomic group including atoms mutually bonded in a crystal model is created as a fragment model. For example, refer to Japanese Laid-Open Patent Publication No. 2014-102569.

### SUMMARY

According to an aspect of an embodiment, a recording medium stores therein an information processing program for causing a computer to execute a process including: obtaining a fragment count by which a structure of a molecule-under-analysis containing a plurality of atoms is divided, information specifying an orbital count of each of the plurality of atoms, and coordinates of each of the plurality of atoms; based on the obtained information and the obtained coordinates, executing: as a first process, assigning among the plurality of atoms, two or more atoms, a number thereof being equal to the obtained fragment count, the two or more atoms being assigned in descending order of the orbital count, respectively, to two or more fragments, a number thereof being equal to the obtained fragment count; as a second process, assigning, with respect to each of the two or more fragments, an atom that of remaining atoms exclusive of the two or more atoms among the plurality of atoms, is close in distance to another atom already assigned to the each of the two or more fragments; assigning the plurality of atoms to the two or more fragments; and outputting the two or more fragments to which the plurality of atoms are assigned.

An object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an explanatory diagram depicting one example of an information processing method according to an embodiment.

FIG. 2 is an explanatory diagram depicting an example of an information processing system 200.

FIG. 3 is a block diagram of an example of a hardware configuration of an information processing device 100.

FIG. 4 is a block diagram depicting an example of a functional configuration of the information processing device 100.

FIG. 5 is an explanatory diagram depicting a flow of operation of the information processing device 100.

FIG. 6 is an explanatory diagram depicting an assignment policy.

FIG. 7 is an explanatory diagram depicting an example of input data 700.

FIG. 8 is an explanatory diagram depicting an example of a periodic table 800.

FIG. 9 is an explanatory diagram depicting an example of assigning atoms to fragments.

FIG. 10 is an explanatory diagram depicting an example of assigning atoms to fragments.

FIG. 11 is an explanatory diagram depicting an example of assigning atoms to fragments.

FIG. 12 is an explanatory diagram depicting an example of assigning atoms to fragments.

FIG. 13 is an explanatory diagram depicting an example of assigning atoms to fragments.

FIG. 14 is an explanatory diagram depicting an example of assigning atoms to fragments.

FIG. 15 is an explanatory diagram depicting an example of output data 1500.

FIG. 16 is a flowchart depicting an example of an overall processing procedure.

FIG. 17 is a flowchart depicting an example of an assignment process procedure.

### DESCRIPTION OF EMBODIMENTS

First, problems associated with the conventional techniques are discussed. In the prior art, however, even when the density matrix embedding theory is used, it may be difficult to reduce the amount of processing in the quantum chemical calculation. For example, it is not clear how to properly divide a molecular structure into multiple fragments in order to reduce the amount of processing required for the quantum chemical calculations.

A recording medium, an information processing method, and an information processing device according to an embodiment of the present disclosure are described in detail with reference to the accompanying drawings.

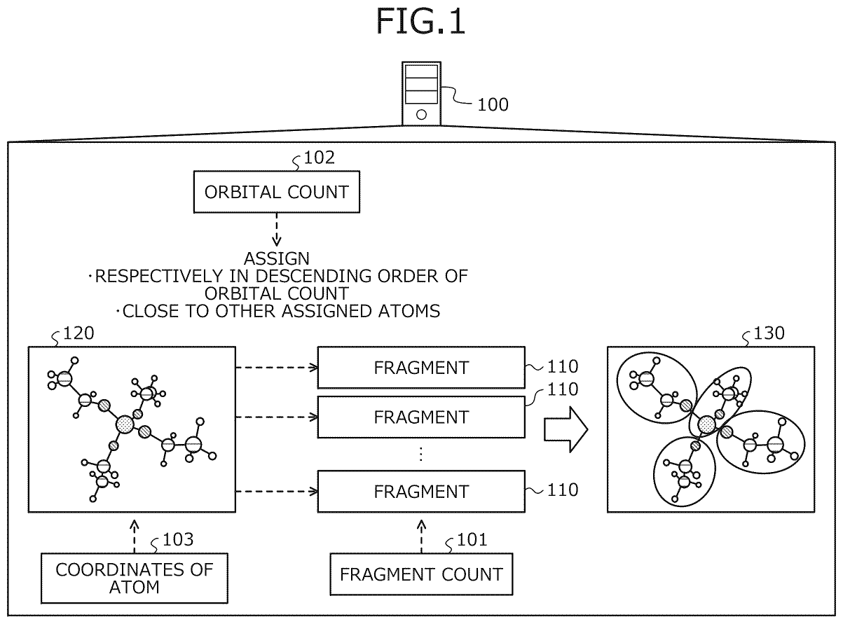

FIG. 1 is an explanatory diagram depicting one example of an information processing method according to an embodiment. An information processing device 100 is a computer for facilitating proper division of a molecular structure into multiple fragments when performing quantum chemical calculations using the density matrix embedding theory. The information processing device 100 is, for example, a server or a personal computer (PC).

Conventionally, in the fields of drug development or material development, it is desirable to perform quantum chemical calculations to calculate the ground-state energy or excitation energy of a molecule. Here, the larger the scale of the molecule, the greater the processing load tends to be when calculating the ground-state energy of the molecule. For example, depending on the basis function set, the larger the scale of the problem, the greater the processing load tends to be when calculating the ground-state energy of the molecule.

In addition, the higher the accuracy of calculating the ground-state energy of the molecule, the greater the processing load tends to be when calculating the ground-state energy of the molecule. For example, among multiple methods that are approximate solution methods for calculating an approximate solution of the ground-state energy of a molecule, a method that has a relatively high accuracy of calculating the approximate solution tends to require a larger processing load when calculating the ground-state energy of the molecule than a method that has a relatively low accuracy of calculating the approximate solution. The approximate solution method includes, for example, the Hartree-Fock (HF) method, the Möller-Plesset method, and the Coupled Cluster (CC) method. For example, the CC method, which calculates the ground-state energy of a molecule with high accuracy, and the full configuration interaction (FCI) method, which is an exact solution method, tend to require a larger amount of processing when calculating the ground-state energy of a molecule than other solution methods.

It is therefore desirable to reduce the amount of processing required when performing quantum chemical calculations. In response to this, there is the density matrix embedding theory that divides the structure of a molecule into multiple fragments and then calculates the ground-state energy of the molecule in order to reduce the amount of processing required when performing quantum chemical calculations. The density matrix embedding theory is also called DMET. In the following description, the density matrix embedding theory may be written as “DMET”.

In DMET, for example, based on the embedded Hamiltonian including the Bass orbital expressing the interaction between fragments, the calculations of the number of electrons and energy of each fragment are repeated while updating the variation parameters so that the total number of electrons of each fragment matches the total number of electrons of the molecule. In DMET, for example, the total energy of the fragments becomes the ground-state energy of the entire molecule.

Here, in DMET, the accuracy of calculating the ground-state energy of the entire molecule depends on how the structure of the molecule is divided into multiple fragments. For example, the smaller the fragment count, the higher the accuracy of calculating the ground-state energy of the entire molecule tends to be. On the other hand, the larger the fragment count, the lower the processing load required for performing the quantum chemical calculation tends to be. In addition, it is considered that the accuracy of calculating the ground-state energy of the entire molecule differs depending on the pattern of dividing the structure of the molecule into multiple fragments, even when the fragment count is the same.

For this reason, even when DMET is used, it may be difficult to reduce the processing load while maintaining the accuracy of the quantum chemical calculation. For example, it is not clear how to properly divide a molecular structure into multiple fragments in order to reduce the amount of processing while maintaining the accuracy of quantum chemical calculation. For example, no method has been proposed for dividing a molecular structure into multiple fragments so as to reduce the amount of processing in quantum chemical calculation while maintaining the accuracy of calculating the ground-state energy of the entire molecule.

Also, for example, the larger the scale of a molecule, the greater the number of patterns for dividing the molecular structure into multiple fragments. For this reason, it is difficult to consider which pattern the molecular structure should be divided into multiple fragments. For example, there is a problem in that the workload and work time imposed on an operator increases when considering which pattern the molecular structure should be divided into multiple fragments.

Thus, in the present embodiment, an information processing method is described that may easily reduce the amount of processing. For example, according to this information processing method, the molecular structure may be divided into multiple fragments so as to reduce the amount of processing in quantum chemical calculation while maintaining the accuracy of calculating the ground-state energy of the entire molecule.

In FIG. 1, the information processing device 100 obtains a fragment count 101. The fragment count 101 indicates into how many fragments a structure 120 of a molecule-under-analysis including multiple atoms is to be divided. The information processing device 100 obtains the fragment count 101 by, for example, accepting an input of the fragment count 101 in response to an operation input by a user. The information processing device 100 may obtain the fragment count 101 by, for example, receiving the fragment count 101 from another computer.

The information processing device 100 obtains an orbital count 102 of each of multiple atoms. The information processing device 100 obtains the orbital count 102 of each of the multiple atoms by, for example, searching for the orbital count 102 of each of the multiple atoms by referring to a periodic table stored in advance. The information processing device 100 may obtain the orbital count 102 of each of the multiple atoms by, for example, accepting an input of the orbital count 102 of each of the multiple atoms in response to an operation input by a user. The information processing device 100 may, for example, obtain the orbital count 102 of each of the multiple atoms by receiving the orbital count 102 of each of the multiple atoms from another computer.

The information processing device 100 obtains coordinates 103 of each of the multiple atoms. The information processing device 100 obtains the coordinates 103 of each of the multiple atoms by accepting input of the coordinates 103 of each of the multiple atoms in response to, for example, an operation input by a user. The information processing device 100 may, for example, obtain the coordinates 103 of each of the multiple atoms by receiving the coordinates 103 of each of the multiple atoms from another computer.
(1-1) The information processing device 100 assigns atoms to two or more fragments 110, the number of which is equal to the obtained fragment count 101, based on the obtained orbital count 102 and the obtained coordinates 103. At this time, among the multiple atoms, the information processing device 100 assigns, for example, two or more atoms, the number of which is equal to the obtained fragment count 101, in descending order of the orbital count 102, to two or more fragments 110, respectively. Furthermore, among the remaining atoms exclusive of the two or more assigned atoms among the multiple atoms, the information processing device 100 assigns to the fragments 110, for example, atoms close to other atoms already assigned to the fragments 110. Close means, for example, that the distance between the atoms is relatively short.

This allows the information processing device 100 to determine how to properly divide the molecular structure into two or more fragments so as to reduce the amount of processing of the quantum chemical calculation while maintaining the accuracy of the calculation of the ground-state energy of the entire molecule. The information processing device 100 may suitably divide the molecular structure into two or more fragments.
(1-2) The information processing device 100 outputs the two or more fragments 110 into which the multiple atoms are assigned. The output format may be, for example, display on a display, print out on a printer, transmission to another computer, or storage in a memory area. The other computer may be, for example, a computer capable of performing quantum chemical calculations. The information processing device 100 outputs, for example, information indicating each of the one or more atoms assigned to the fragments in association with information indicating each of the two or more fragments.

This allows the information processing device 100 to use the two or more fragments obtained by suitably dividing the molecular structure. Therefore, the information processing device 100 may use DMET to perform quantum chemical calculations based on the two or more fragments obtained by suitably dividing the molecular structure. The information processing device 100 may reduce the amount of processing required when performing quantum chemical calculations while maintaining the accuracy of the calculation of the ground-state energy of the entire molecule. The information processing device 100 may reduce the workload and work time required by a user who wishes to divide the molecular structure into two or more fragments.
(1-3) The information processing device 100 may use DMET to perform quantum chemical calculations based on two or more fragments 110 stored in the storage area of the device. This allows the information processing device 100 to calculate the ground-state energy of the entire molecule. The information processing device 100 may reduce the amount of processing required when performing quantum chemical calculations while maintaining the accuracy of calculating the ground-state energy of the entire molecule.

Here, while a case where the information processing device 100 obtains the orbital count 102 of each of the multiple atoms is described, the present disclosure is not limited hereto. For example, the information processing device 100 may obtain a periodic number proportional to the orbital count 102 of each of the multiple atoms. In this case, the information processing device 100 assigns the two or more atoms to the two or more fragments 110, respectively, in descending order of the orbital count 102 of the multiple atoms based on the periodic number of each atom.

Here, while a case where the function of the information processing device 100 is implemented by a single computer is described, the present disclosure is not limited hereto. For example, the function of the information processing device 100 may be implemented by cooperation of multiple computers. For example, the function of the information processing device 100 may be implemented on a cloud.

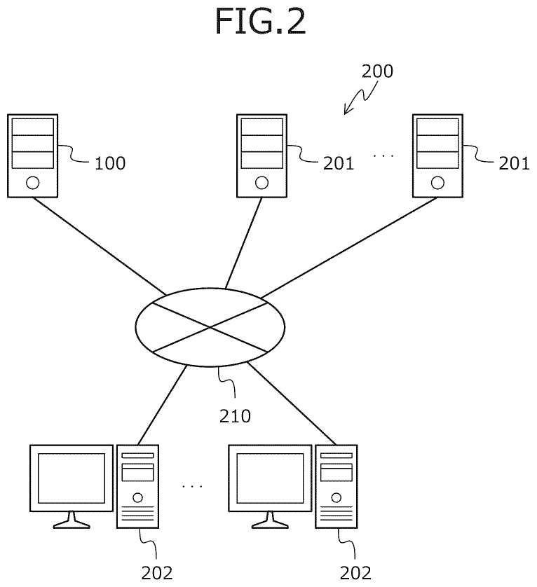

Next with reference to FIG. 2, an example of an information processing system 200 will be described to which the information processing device 100 depicted in FIG. 1 is applied.

FIG. 2 is an explanatory diagram depicting an example of the information processing system 200. In FIG. 2, the information processing system 200 includes the information processing device 100, one or more chemical calculation devices 201, and one or more client devices 202.

In the information processing system 200, the information processing device 100 and the chemical calculation device 201 are connected via a wired or wireless network 210. The network 210 is, for example, a local area network (LAN), a wide area network (WAN), the Internet, or the like. In the information processing system 200, the information processing device 100 and the client device 202 are connected via the wired or wireless network 210.

The information processing device 100 is a computer for dividing a molecular structure into two or more fragments. The information processing device 100 obtains a processing request requesting that a quantum chemical calculation be performed on a molecule-under-analysis using DMET. The processing request includes, for example, the structure of the molecule-under-analysis.

The structure of the molecule-under-analysis includes, for example, the coordinates of each of the multiple atoms forming the molecule-under-analysis. The structure of the molecule-under-analysis includes, for example, the type of each of the multiple atoms forming the molecule-under-analysis. The processing request includes, for example, the fragment count.

The information processing device 100 obtains the structure of the molecule-under-analysis and the fragment count based on the processing request. The information processing device 100 obtains, for example, the coordinates of each atom and the type of each atom, based on the processing request. The information processing device 100 stores a periodic table. The periodic table is information that indicates the type of atom and the orbital count of the atom in association with each other. The information processing device 100 refers to the periodic table and obtains the orbital count of each atom based on the type of each atom.

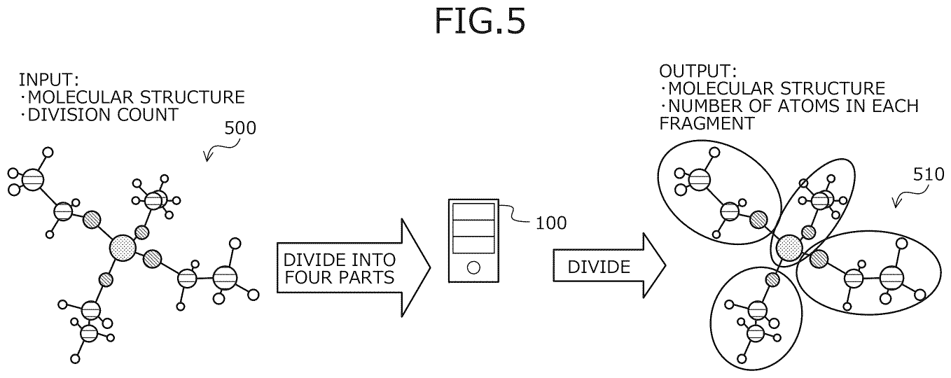

The information processing device 100 prepares two or more fragments, the number of which is equal to the obtained fragment count. The information processing device 100 divides the structure of the molecule-under-analysis into two or more fragments by assigning each atom to two or more fragments based on the coordinates of each atom and the orbital count of each atom. Specific examples of assignment will be described later with reference to, for example, FIGS. 5 to 14.

The information processing device 100 outputs the two or more fragments into which multiple atoms are assigned. The output format is, for example, display on a display, printout on a printer, transmission to another computer, or storage to a storage area. The other computer is, for example, the chemical calculation device 201. The information processing device 100 transmits, for example, a calculation request to perform a quantum chemical calculation on the molecule-under-analysis using DMET, the calculation request being transmitted to any one of the chemical calculation devices 201. The calculation request includes, for example, two or more fragments. The calculation request includes the structure of the molecule-under-analysis.

The information processing device 100 receives a result of performing a quantum chemical calculation on the molecule-under-analysis from any of the chemical calculation devices 201. The information processing device 100 outputs the result of performing the quantum chemical calculation on the molecule-under-analysis. The information processing device 100 transmits, for example, the results of the quantum chemical calculation performed on the molecule-under-analysis to the client device 202. The information processing device 100 may output, for example, the results of the quantum chemical calculation performed on the molecule-under-analysis so that the user may refer to the results. The information processing device 100 is, for example, a server or a PC.

The chemical calculation device 201 is a computer that performs quantum chemical calculations on molecules. Any one of the chemical calculation devices 201 receives a calculation request from the information processing device 100 requesting that a quantum chemical calculation be performed on the molecule-under-analysis using DMET. Based on the calculation request, the one of the chemical calculation devices 201 obtains the structure of the molecule-under-analysis and two or more fragments.

Based on the structure of the molecule-under-analysis and two or more fragments, the one of the chemical calculation devices 201 performs therein a quantum chemical calculation on the molecule-under-analysis using DMET. The one of the chemical calculation devices 201 may perform a quantum chemical calculation on the molecule-under-analysis by parallel processing using DMET in cooperation with other chemical calculation devices 201 based on the structure of the molecule-under-analysis and two or more fragments.

The one of the chemical calculation devices 201 generates a result of performing the quantum chemical calculation on the molecule-under-analysis. The result includes, for example, the ground-state energy of the molecule-under-analysis. The result may include, for example, the number of electrons of the molecule-under-analysis. The one of the chemical calculation devices 201 may, for example, communicate with other chemical calculation devices 201 and generate a result of performing a quantum chemical calculation on the molecule-under-analysis. The one of the chemical calculation devices 201 transmits the result of performing the quantum chemical calculation on the molecule-under-analysis to the information processing device 100. The chemical calculation device 201 is, for example, a server or a PC. The chemical calculation device 201 may be, for example, a quantum computer.

The client device 202 is a computer used by a user who wishes to perform a quantum chemical calculation on the molecule-under-analysis. The user is, for example, an operator. The client device 202 generates a processing request for performing a quantum chemical calculation on a molecule-under-analysis using DMET in response to an operation input by a user. The client device 202 obtains, for example, the structure and the fragment count of the molecule-under-analysis in response to an operation input by a user. The client device 202 generates a processing request including, for example, the structure and the fragment count of the molecule-under-analysis.

The client device 202 transmits the generated processing request to the information processing device 100. The client device 202 receives the result of the quantum chemical calculation performed on the molecule-under-analysis from the information processing device 100. The client device 202 outputs the result of the quantum chemical calculation performed on the molecule-under-analysis so that the user may refer to the result. The client device 202 is, for example, a PC, a tablet terminal, or a smartphone.

Here, while a case where the information processing device 100 is a device different from the chemical calculation device 201 is described, configuration is not limited hereto. For example, the information processing device 100 may have a function as the chemical calculation device 201 and may also operate as the chemical calculation device 201. In this case, the information processing system 200 may omit the chemical calculation device 201.

Here, while a case where the information processing device 100 is a different device from the client device 202 is described, configuration is not limited hereto. For example, the information processing device 100 may have a function as the client device 202 and also operate as the client device 202. In this case, the information processing system 200 may omit the client device 202.

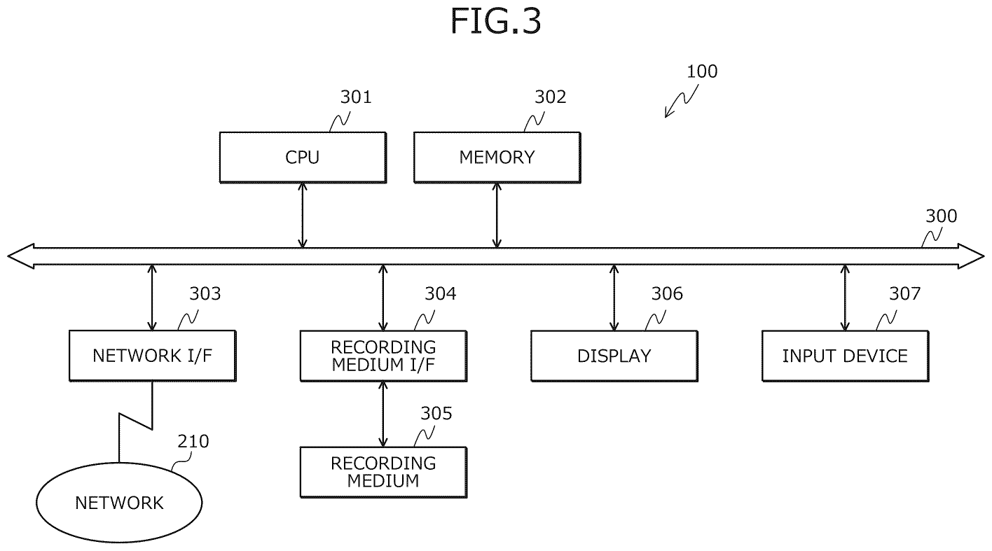

Next, with reference to FIG. 3, an example of hardware configuration of the information processing device 100 is described.

FIG. 3 is a block diagram of an example of a hardware configuration of the information processing device 100. In FIG. 3, the information processing device 100 has a central processing unit (CPU) 301, a memory 302, and a network interface (I/F) 303. Further, the information processing device 100 further has a recording medium I/F 304, a recording medium 305, a display 306, and an input device 307. Further, the components are connected to each other by a bus 300.

The CPU 301 governs overall control of the information processing device 100. The memory 302, for example, includes a read-only memory (ROM), a random-access memory (RAM) and a flash ROM. In particular, for example, the flash ROM and the ROM store various types of pf programs and the RAM is used as a work area of the CPU 301. Programs stored in the memory 302 are loaded onto the CPU 301, whereby encoded processes are executed by the CPU 301.

The network I/F 303 is connected to the network 210 through a communications line and is connected to other computers via the network 210. Further, the network I/F 303 administers an internal interface with the network 210 and controls the input and output of data with respect to other computers. The network I/F 303, for example, is a modem or a LAN adapter.

The recording medium I/F 304, under the control of the CPU 301, controls the reading and writing of data with respect to the recording medium 305. The recording medium I/F 304 is, for example, a disk drive, a solid-state drive (SSD), a universal serial bus (USB) port, or the like. The recording medium 305 is a nonvolatile memory storing therein data written thereto under the control of the recording medium I/F 304. The recording medium 305 is, for example, a disk, a semiconductor memory, a USB memory, or the like. The recording medium 305 may be removable from the information processing device 100.

The display 306 displays, a cursor, icons, a toolbox, documents, images, or data such as functional information. The display 306 is, for example, a cathode ray tube (CRT), a liquid crystal display, or an organic electroluminescence (EL) display, etc. The input device 307 has keys for inputting characters, numerals, or various types of instructions and performs an input of data. The input device 307 is, for example, a keyboard or a mouse, etc. The input device 307, for example, may be a touch-panel type input pad or a ten-key device, etc.

The information processing device 100, in addition to the described components, may further have, for example, a camera or the like. Further, in addition to the components above, the information processing device 100 may further have, for example, a printer, a scanner, a microphone, or a speaker.

Further, the information processing device 100 may have, for example, the recording medium I/F 304 and the recording medium 305 in plural. Further, the information processing device 100, for example, may omit the display 306, the input device 307, or the like. Further, the information processing device 100, for example, may omit the recording medium I/F 304 and the recording medium 305.

The hardware configuration of the chemical calculation device 201 is, for example, similar to the hardware configuration of the information processing device 100 depicted in FIG. 3 and therefore, description thereof is omitted.

The hardware configuration of the client device 202 is, for example, similar to the hardware configuration of the information processing device 100 depicted in FIG. 3 and therefore, a description thereof is omitted.

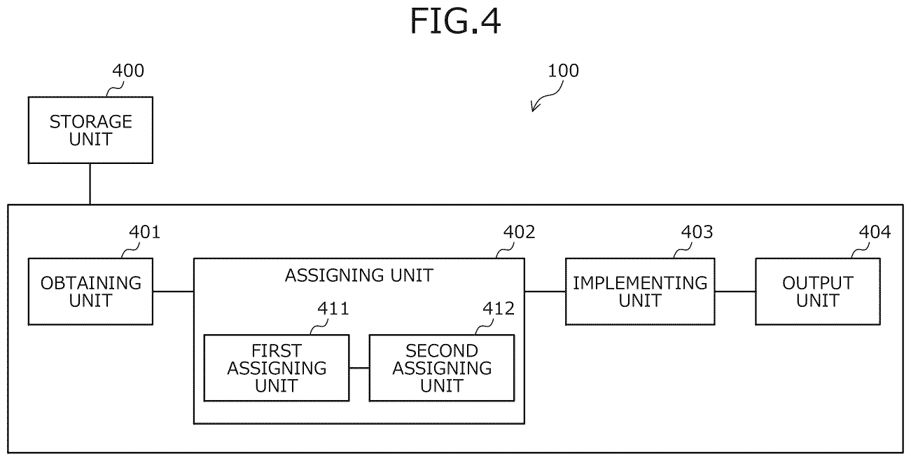

Next, with reference to FIG. 4, an example of a functional configuration of the information processing device 100 will be described.

FIG. 4 is a block diagram depicting an example of the functional configuration of the information processing device 100. The information processing device 100 includes a storage unit 400, an obtaining unit 401, an assigning unit 402, an implementing unit 403, and an output unit 404. The assigning unit 402 includes a first assigning unit 411 and a second assigning unit 412.

The storage unit 400 is implemented by, for example, a storage area such as the memory 302 or the recording medium 305 depicted in FIG. 3. In the following, while a case where the storage unit 400 is included in the information processing device 100 will be described, configuration is not limited hereto. For example, the storage unit 400 may be included in a device different from the information processing device 100, and the contents stored in the storage unit 400 may be referred to by the information processing device 100.

The obtaining unit 401 to the output unit 404 function as an example of a control unit. For example, respective functions of the obtaining unit 401 to the output unit 404 may be implemented by, for example, causing the CPU 301 to execute a program stored in a storage area such as the memory 302 or the recording medium 305 depicted in FIG. 3, or by the network I/F 303. The processing results of each functional unit are stored to, for example, a storage area such as the memory 302 or the recording medium 305 depicted in FIG. 3.

The storage unit 400 stores various types of information that is referred to or updated in the processing by the functional units. The storage unit 400 stores, for example, a structure of a molecule-under-analysis including multiple atoms. The structure of the molecule-under-analysis includes, for example, the coordinates of each of the multiple atoms forming the molecule-under-analysis. The structure of the molecule-under-analysis includes, for example, the type of each of the multiple atoms forming the molecule-under-analysis. The structure of the molecule-under-analysis is obtained, for example, by the obtaining unit 401.

The storage unit 400 stores, for example, the fragment count into which the structure of the molecule-under-analysis is divided. The fragment count is obtained, for example, by the obtaining unit 401. The fragment count may be set, for example, by the user in advance. The storage unit 400 stores, for example, a periodic table that depicts the type of atom and the orbital count of the atom in association with each other. The periodic table is obtained, for example, by the obtaining unit 401. The periodic table may be set, for example, by the user in advance.

The storage unit 400 stores, for example, orbital count information that specifies the orbital count of each of the multiple atoms. The orbital count information is, for example, the orbital count of each atom itself. The orbital count information may be, for example, a periodic number proportional to the orbital count of each atom. The orbital count information is obtained by, for example, the obtaining unit 401.

The obtaining unit 401 obtains various types of information used in the processing by the functional units. The obtaining unit 401 stores the obtained various types of information to the storage unit 400 or outputs the obtained information to the functional units. The obtaining unit 401 may also output various types of information stored in the storage unit 400 to the functional units. The obtaining unit 401 obtains various types of information based on, for example, an operation input by the user. The obtaining unit 401 may receive various types of information from, for example, a device other than the information processing device 100.

The obtaining unit 401 obtains, for example, a periodic table. For example, the obtaining unit 401 obtains the periodic table by accepting an input of the periodic table. For example, the obtaining unit 401 may obtain the periodic table by receiving the periodic table from another computer. The other computer is, for example, the client device 202.

The obtaining unit 401 obtains, for example, a processing request requesting that the structure of the molecule-under-analysis be divided into two or more fragments. The processing request may further request that a quantum chemical calculation be performed on the molecule-under-analysis using DMET. The processing request may include, for example, the structure of the molecule-under-analysis. The processing request may include, for example, the fragment count. The processing request may include, for example, orbital count information.

For example, the obtaining unit 401 obtains the processing request by accepting an input of the processing request. For example, the obtaining unit 401 may obtain the processing request by receiving the processing request from another computer. The other computer is, for example, the client device 202.

The obtaining unit 401 obtains, for example, the structure of the molecule-under-analysis. For example, the obtaining unit 401 obtains the structure of the molecule-under-analysis by extracting the structure of the molecule-under-analysis from the processing request. For example, the obtaining unit 401 may obtain the structure of the molecule-under-analysis by accepting an input of the structure of the molecule-under-analysis. The obtaining unit 401 may, for example, obtain the structure of the molecule-under-analysis by receiving the structure of the molecule-under-analysis from another computer. The other computer is, for example, the client device 202.

The obtaining unit 401 may obtain, for example, the fragment count. The obtaining unit 401 may, for example, obtain the fragment count by extracting the fragment count from a processing request. The obtaining unit 401 may, for example, obtain the fragment count by accepting an input of the fragment count. The obtaining unit 401 may, for example, obtain the fragment count by receiving the fragment count from the other computer. The other computer is, for example, the client device 202.

The obtaining unit 401 may obtain, for example, orbital count information. The obtaining unit 401 may, for example, obtain the orbital count information by extracting the orbital count information from a processing request. The obtaining unit 401 may, for example, obtain the orbital count information by accepting an input of the orbital count information. The obtaining unit 401, for example, may obtain the orbital count information by receiving the orbital count information from the other computer. The other computer is, for example, the client device 202. The obtaining unit 401 may obtain the orbital count information by, for example, referring to the periodic table and identifying the orbital count information.

The obtaining unit 401 may receive a start trigger for starting the processing by any of the functional units. The start trigger may be, for example, a predetermined operation input by the user. The start trigger may be, for example, reception of predetermined information from another computer. The start trigger may be, for example, a case where any of the functional units outputs predetermined information. The obtaining unit 401 regards, for example, the receipt of a processing request as a start trigger for starting the processing of the assigning unit 402 and the implementing unit 403.

The assigning unit 402 prepares two or more fragments, the number of which is equal to the fragment count obtained by the obtaining unit 401. The assigning unit 402 assigns the multiple atoms to two or more fragments by the first assigning unit 411 and the second assigning unit 412, based on the orbital count information obtained by the obtaining unit 401 and the coordinates of each atom obtained by the obtaining unit 401. As a result, the assigning unit 402 may suitably divide the structure of the molecule-under-analysis into two or more fragments, and may reduce the amount of processing required when performing the quantum chemical calculation while maintaining the accuracy of the quantum chemical calculation.

Of the multiple atoms, the first assigning unit 411 assigns two or more of the atoms, the number of which is equal to the fragment count, the first assigning unit 411 assigning, respectively, the two or more atoms to two or more fragments in descending order of the orbital count based on the orbital count information and the coordinates of each atom. The first assigning unit 411, for example, selects one of the two or more fragments as a first fragment. Among one or more first atoms having the largest orbital count among the multiple atoms, the first assigning unit 411, for example, extracts and assigns one of the first atoms to the selected first fragment.

Among the two or more fragments, the first assigning unit 411, for example, sequentially selects each of remaining second fragments exclusive of the selected first fragment once each. For example, each time the first assigning unit 411 selects a second fragment, the first assigning unit 411 extracts a second atom close to one of the extracted first atoms, from among one or more second atoms having the largest orbital count among the multiple atoms, and assigns the extracted second atom to the second fragment. In this way, the first assigning unit 411 may assign the first atoms to the two or more fragments.

Among the remaining atoms exclusive of the two or more atoms already extracted among the multiple atoms, the second assigning unit 412 assigns, to a fragment, an atom close to the other atoms already assigned to fragments, based on the orbital count information and the coordinates of each atom. For example, the second assigning unit 412 recursively selects one of the two or more fragments sequentially. For example, each time the second assigning unit 412 selects a fragment, the second assigning unit 412 extracts, from among one or more third atoms having the largest orbital count among the remaining atoms, a third atom close to the atom most recently assigned to a fragment and assigns the selected third atom to the fragment. As a result, the second assigning unit 412 may assign all the multiple atoms to the two or more fragments.

The implementing unit 403 performs a quantum chemical calculation according to DMET based on the two or more fragments to which the assigning unit 402 assigns the multiple atoms. The implementing unit 403 generates a result of the quantum chemical calculation. The result includes, for example, the ground-state energy of the molecule-under-analysis. The result may include, for example, the number of electrons of the molecule-under-analysis. As a result, the implementing unit 403 can perform the quantum chemical calculation accurately and efficiently.

The implementing unit 403 may control one or more chemical calculation devices 201 to perform a quantum chemical calculation according to DMET based on the two or more fragments to which the assigning unit 402 assigns multiple atoms. The implementing unit 403 receives a result of the quantum chemical calculation from the chemical calculation device 201. As a result, the implementing unit 403 can perform the quantum chemical calculation accurately and efficiently.

The output unit 404 outputs the processing result of at least any one of the functional units. The output format is, for example, display on a display, print output to a printer, transmission to an external device via the network I/F 303, or storage in a storage area such as the memory 302 or the recording medium 305. In this way, the output unit 404 can notify the user of the processing result of at least any one of the functional units, thereby improving the convenience of the information processing device 100.

The output unit 404 outputs, for example, two or more fragments into which multiple atoms are assigned. For example, the output unit 404 outputs information indicating each of the one or more atoms assigned to the fragments in association with information indicating each of the two or more fragments.

More specifically, the output unit 404 outputs information indicating each of the one or more atoms assigned to the fragments in association with information indicating each of the two or more fragments so that the user can refer to the information. More specifically, the output unit 404 may transmit information indicating each of the one or more atoms assigned to the fragments to another computer in association with information indicating each of the two or more fragments. In this way, the output unit 404 can make two or more fragments to which multiple atoms are assigned available. As a result, the output unit 404 can reduce the amount of processing required when performing the quantum chemical calculation while maintaining the accuracy of the quantum chemical calculation.

The output unit 404 outputs, for example, a result of the quantum chemical calculation. For example, the output unit 404 outputs the result of the quantum chemical calculation so that the user can refer to it. For example, the output unit 404 may transmit the result of the quantum chemical calculation to another computer. In this way, the information processing device 100 can make the result of the quantum chemical calculation available.

An example of the operation of the information processing device 100 will then be described with reference to FIGS. 5 to 14. First, a flow of the operation of the information processing device 100 will be described with reference to FIG. 5.

FIG. 5 is an explanatory diagram depicting the flow of the operation of the information processing device 100. In FIG. 5, the information processing device 100 obtains a structure 500 of a molecule-under-analysis. The structure 500 includes the type of each of the multiple atoms forming the molecule-under-analysis and the coordinates of each atom.

In the example of FIG. 5, the molecule-under-analysis is for example tetraethoxysilane. Tetraethoxysilane is also called tetraethyl orthosilicate (TEOS). In the example of FIG. 5, the multiple atoms are for example a Si atom, four O atoms, eight C atoms, and twenty H atoms.

In addition, the information processing device 100 obtains a division count indicating into how many fragments the molecule-under-analysis structure 500 is to be divided. The division count corresponds to the fragment count. In the example of FIG. 5, the division count is for example 4.

The information processing device 100 stores a periodic table. The information processing device 100 refers to the periodic table and obtains the orbital count of each of the multiple atoms. The information processing device 100 prepares multiple fragments equal in number to the obtained number of divisions.

The information processing device 100 divides the structure 500 of the molecule-under-analysis into multiple fragments so as to equalize the amount of processing between the fragments while maintaining the accuracy of the quantum chemical calculation. Here, the problem scale of the quantum chemical calculation has a property that it depends on the orbital count of the atoms. Therefore, the information processing device 100 divides the structure 500 of the molecule-under-analysis into multiple fragments by assigning the multiple atoms to multiple fragments based on the orbital count of each atom.

For example, when the information processing device 100 finishes dividing the structure 500 of the molecule-under-analysis into multiple fragments, the information processing device 100 outputs the structure 510 of the molecule-under-analysis after dividing the molecule-under-analysis into multiple fragments. In the structure 510, circles each indicate the range of one fragment. For example, when the information processing device finishes dividing the structure 500 of the molecule-under-analysis into multiple fragments, the information processing device 100 outputs the number of atoms of each of the multiple fragments.

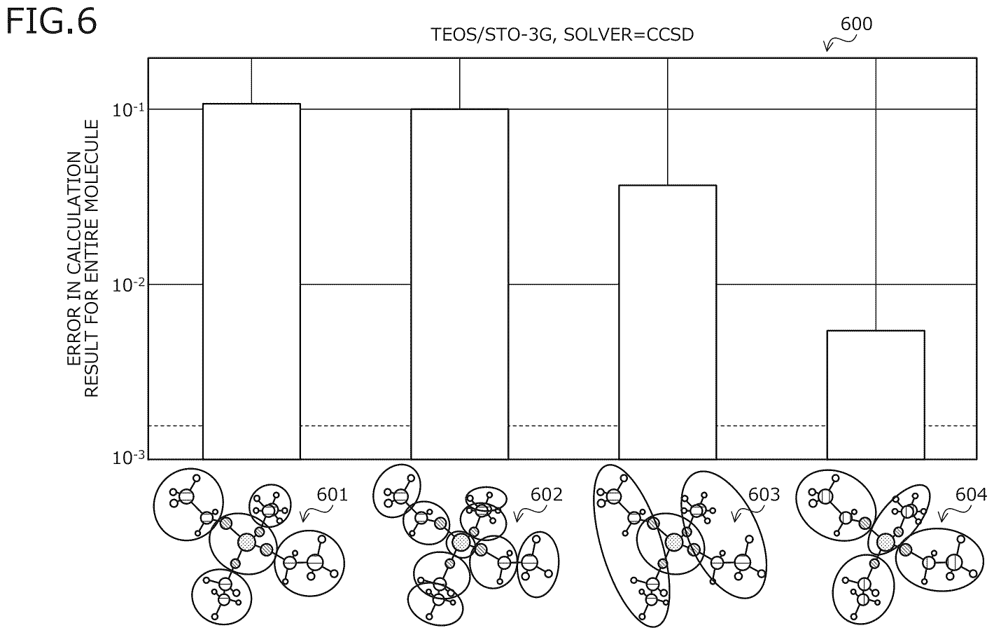

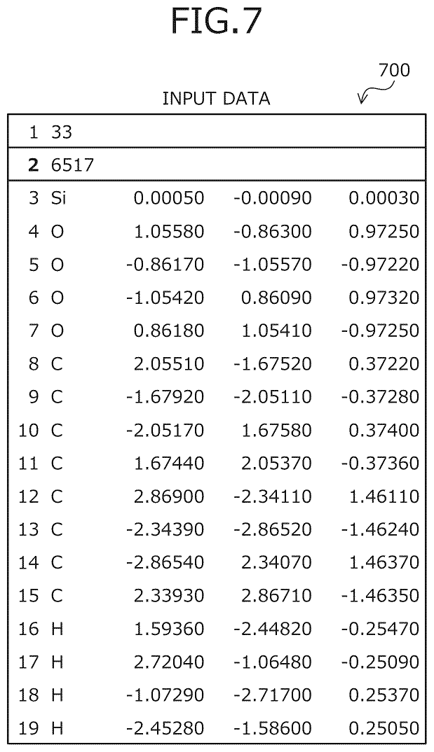

In the following, a policy for assigning multiple atoms to multiple fragments by the information processing device 100 will be considered with reference to FIG. 6, and then an example of assigning multiple atoms to multiple fragments by the information processing device 100 will be described with reference to FIGS. 7 to 14. Here, FIG. 6 will first be described.

FIG. 6 is an explanatory diagram depicting an assignment policy. A graph 600 in FIG. 6 depicts the accuracy of quantum chemical calculations in patterns 601 to 604 for dividing a TEOS molecule into multiple fragments. The accuracy is evaluated, for example, by the error in the calculation results of the quantum chemical calculations for the entire TEOS molecule. The smaller the error value, the better. The basis function set used in carrying out the quantum chemical calculations is STO-3G. The solution method used in carrying out the quantum chemical calculations is CCSD, which is a type of CC method. Moreover, in the patterns 601 to 604, each circle indicates the range of one fragment.

Here, as depicted in the graph 600, it is considered that the smaller the number of divisions is, the higher the accuracy of the quantum chemical calculations is. For example, the patterns 603 and 604 have higher accuracy of the quantum chemical calculations than the patterns 601 and 602. On the other hand, it is also considered that the larger the number of divisions, the lower the amount of processing required when performing the quantum chemical calculations. There is a trade-off between maintaining the accuracy of the quantum chemical calculations and reducing the amount of processing required when performing the quantum chemical calculations.

Also, as depicted in the graph 600, it is considered that the longer the diameter of each fragment, the higher the accuracy of the quantum chemical calculations. For example, the patterns 603 and 604 have higher accuracy of the quantum chemical calculations than the patterns 601 and 602. Also, as depicted in the graph 600, it is considered that when atoms present in the vicinity are included in the same fragment, the accuracy of the quantum chemical calculations is higher. For example, the pattern 604 has higher accuracy of the quantum chemical calculations than the pattern 603.

Hence, in consideration of the trade-off between maintaining the accuracy of the quantum chemical calculation and reducing the amount of processing required when performing the quantum chemical calculation, it is preferable that the information processing device 100 accepts the input of the number of divisions in response to the user's operation input and obtains the number of divisions.

Also, it may be preferable as an assignment policy that the information processing device 100 assigns atoms to each fragment in a round robin manner in descending order of the orbital count. This is expected to equalize the orbital count of atoms in each fragment and to easily reduce the amount of processing required when performing the quantum chemical calculation.

Also, it may be preferable as an assignment policy that the atoms that the information processing device 100 assigns first to each fragment are atoms that are present at coordinates close to each other. This is expected to assign atoms that belong to different branches in the structure 500 of the molecule-under-analysis to different fragments and increase the diameter of each fragment.

Also, it may be preferable as an assignment policy that the atoms that the information processing device 100 assigns second and subsequent sessions to the fragments are atoms that are present at coordinates close to the atom that has been assigned to the fragment immediately before. According to this, it is expected that atoms present at coordinates close to each other on the structure 500 of the molecule-under-analysis are assigned to the same fragment, while the diameter of each fragment is increased.

An example of the operation of the information processing device 100 will then be described with reference to FIGS. 7 to 14. For example, an example in which the information processing device 100 assigns multiple atoms to multiple fragments according to the various policies described above will be described. First, the description will shift to FIG. 7.

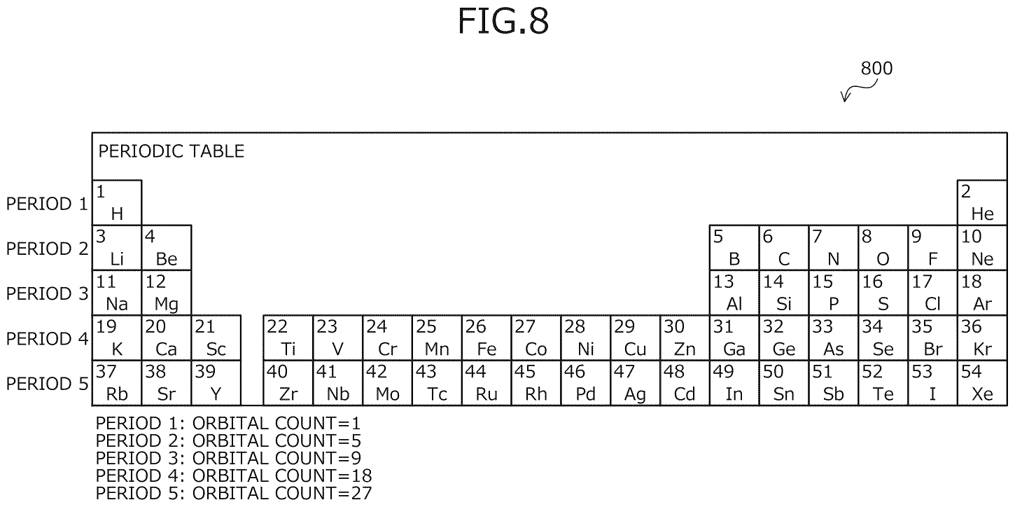

FIG. 7 is an explanatory diagram depicting an example of input data 700. In FIG. 7, the information processing device 100 obtains the input data 700 depicting the structure of a TEOS molecule. The left end of the input data 700 is the line number. The first line of the input data 700 indicates that the number of atoms in the TEOS molecule is 33. The second line of the input data 700 is a comment field. The third and subsequent lines of the input data 700 depict the type of atom and the coordinates of the atom. As an example, FIG. 7 depicts a case in which the type of atom and the coordinates of the atom are arranged in descending order of the orbital count. The type is, for example, Si, O, C, or H. The coordinates are a combination of an x coordinate value, a y coordinate value, and a z coordinate value in a three-dimensional space. Furthermore, the information processing device 100 obtains a division count of 4. The description will then shift to FIG. 8.

FIG. 8 is an explanatory diagram depicting an example of a periodic table 800. In FIG. 8, the information processing device 100 stores the periodic table 800. Each of the atoms in the first row of the periodic table 800 is an atom of period 1. The orbital count of the atoms in period 1 is 1. Each of the atoms in the second row of the periodic table 800 is an atom of period 2. The orbital count of the atoms in period 2 is 5.

Each of the atoms in the third row of the periodic table 800 is an atom of period 3. The orbital count of the atoms in period 3 is 9. Each of the atoms in the fourth row of the periodic table 800 is an atom of period 4. The orbital count of an atom in period 4 is 18. Each of the atoms in the fifth row of the periodic table 800 is an atom in period 5. The orbital count of an atom in period 5 is 27.

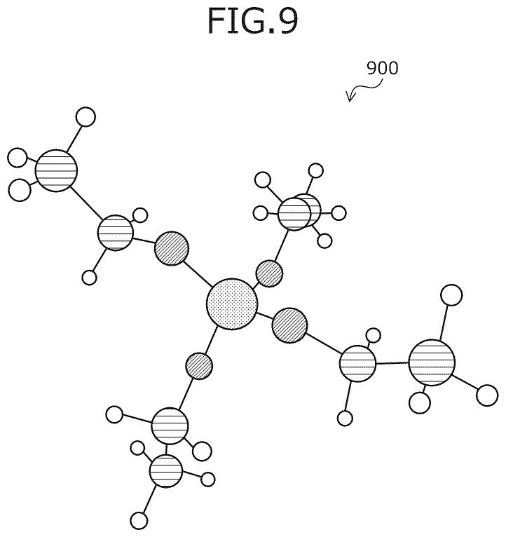

The information processing device 100 generates a periodic dictionary in which multiple atoms forming a TEOS molecule are classified by period based on the input data 700 and the periodic table 800. For example, the periodic dictionary is {“p3”: [Si], “p2” [O0, . . . , O3, C0, . . . , C7], “p1” [H0, . . . , H19]}. px is an index of an atomic group in period x. The numbers after O, C, and H are numbers that identify different atoms of the same type. The description will then shift to FIG. 9.

FIGS. 9, 10, 11, 12, 13, and 14 are explanatory diagrams depicting an example of assigning multiple atoms to multiple fragments. FIG. 9 depicts a structure 900 of a TEOS molecule indicated by the input data 700. In the structure 900 of the TEOS molecule, each circle indicates an atom. The size of the circle corresponds to the size of the periodic number and the orbital count of the atom. The dotted hatched circle corresponds to a Si atom. The diagonal hatched circle corresponds to an O atom. The horizontal hatched circle corresponds to a C atom. The unhatched circle corresponds to an H atom.

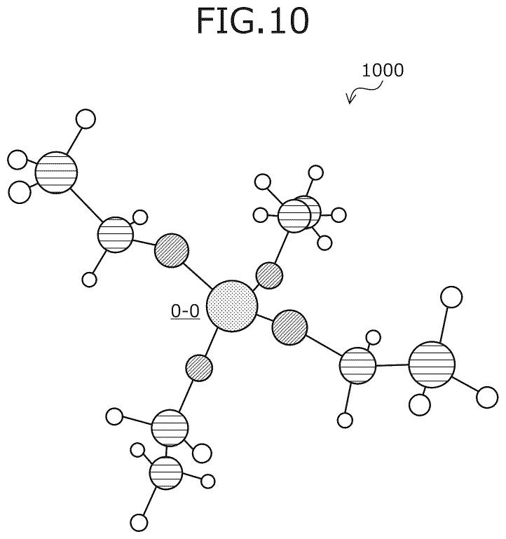

The information processing device 100 prepares multiple fragments, the number of which is equal to the division count. The information processing device 100 prepares, for example, four fragments F_n, n=0, 1, 2, 3. The information processing device 100 also prepares a variable Npop representing the total number of assigned atoms. The initial value of Npop is 1. The description will then shift to FIG. 10.

In FIG. 10, the information processing device 100 extracts the first atom from the atomic group with the maximum period in the periodic dictionary and assigns the extracted first atom to the fragment F_0. Here, the information processing device 100 removes the atom from the periodic dictionary by extracting the atom.

In the example of FIG. 10, as depicted in a pattern 1000, the information processing device 100 extracts the first Si atom from the atomic group “p3”:[Si] and assigns the extracted first Si atom to the fragment F_0. Therefore, the atomic group “p3”:[Si] is deleted from the periodic dictionary, and the result becomes {“p2” [O0, . . . , O3, C0, . . . , C7], “p1” [H0, . . . , H19]}. The initial value 1 of Npop indicates that one atom is assigned to the fragment F_0 here.

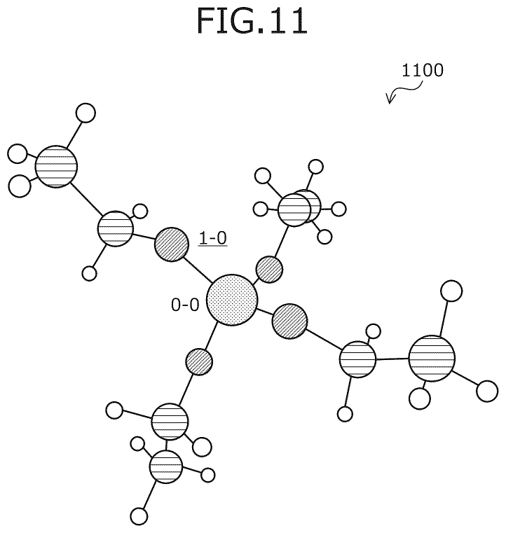

The pattern 1000 indicates which atom is assigned to which fragment F_n in the process of assigning multiple atoms to multiple fragments F_n. The symbol “nm” next to the circle in the figure indicates that the atom corresponding to the circle is assigned to the fragment F_n in the m-th order. m is an integer equal to or greater than 0. The description will then shift to FIG. 11.

In FIG. 11, the information processing device 100 extracts the atomic group with the maximum period in the periodic dictionary. Here, the information processing device 100 deletes the atomic group from the periodic dictionary by extracting the atomic group. In the example of FIG. 11, the information processing device 100 extracts the atomic group “p2” [O0, . . . , O3, C0, . . . , C7] from the periodic dictionary. Therefore, the periodic dictionary becomes {“p1” [H0, . . . , H19]}.

The information processing device 100 determines whether Npop<the number of divisions is satisfied. Since Npop is 1, the information processing device 100 determines that Npop<the number of divisions is satisfied. When Npop<division count is satisfied, the information processing device 100 sets the atom assigned 0th to the fragment F_0 as the reference atom. In the example of FIG. 11, the information processing device 100 sets the Si atom as the reference atom.

Based on the coordinates of the atoms, the information processing device 100 extracts the atom closest to the reference atom from the extracted atomic group “p2” [O0, . . . , O3, C0, . . . , C7] and assigns the extracted atom to the fragment F_(Npop % division count). The Npop % division count indicates the remainder when Npop is divided by the division count.

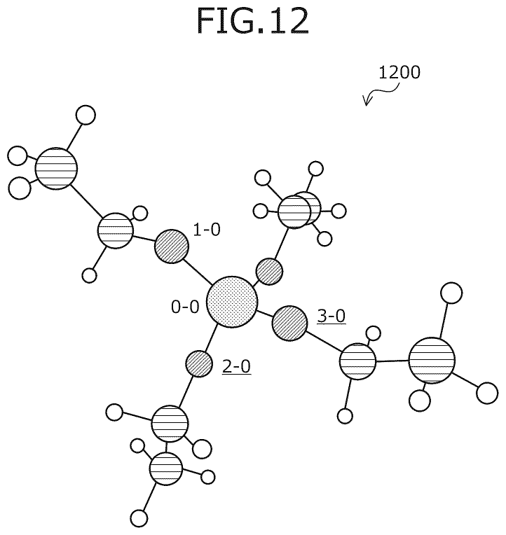

In the example of FIG. 11, as depicted in a pattern 1100, the information processing device 100 extracts the O0 atom closest to the Si atom and assigns the O0 atom to the fragment F_1. In addition, the information processing device 100 adds 1 to Npop in response to assigning the O0 atom to the fragment F_1. Therefore, Npop is 2. The pattern 1100 indicates which atom is assigned to which fragment F_n in the process of assigning multiple atoms to multiple fragments F_n. The description will then shift to FIG. 12.

In FIG. 12, the information processing device 100 determines whether the extracted atomic group is empty. In the example of FIG. 12, the information processing device 100 determines that the extracted atomic group “p2” [O1, . . . , O3, C0, . . . , C7] is not empty.

If the extracted atomic group is not empty, the information processing device 100 determines whether Npop<the number of divisions is satisfied.

Since Npop is 2, the information processing device 100 determines that Npop<the number of divisions is satisfied. When Npop<the number of divisions is satisfied, the information processing device 100 sets the atom assigned 0th to the fragment F_0 as the reference atom. In the example of FIG. 12, the information processing device 100 sets the Si atom as the reference atom.

Based on the coordinates of the atom, the information processing device 100 extracts the atom that is closest to the reference atom from the extracted atomic group “p2” [O1, . . . , O3, C0, . . . , C7] and assigns the extracted atom to fragment F_(Npop % division count). The Npop % division count indicates the remainder when Npop is divided by the division count.

In the example of FIG. 12, as depicted in a pattern 1200, the information processing device 100 extracts the O1 atom that is closest to the Si atom and assigns it to fragment F_2. In addition, the information processing device 100 adds 1 to Npop in response to assigning the O1 atom to fragment F_2. Therefore, Npop becomes 3. The pattern 1200 indicates which atom has been assigned to which fragment F_n in the process of assigning multiple atoms to multiple fragments F_n.

The information processing device 100 repeats the series of processes in the same manner, setting a reference atom, extracting an atom that is closest to the set reference atom from among the extracted atomic group, and assigning the atom to the fragment F_(Npop % division count), until Npop≥division count is satisfied. At this time, when the extracted atomic group becomes empty before Npop≥division count, the information processing device 100 newly extracts an atomic group with the maximum period in the periodic dictionary.

In the example of FIG. 12, the information processing device 100 extracts an O2 atom and assigns the extracted O2 atom to fragment F_3 before Npop≥division count. Furthermore, the information processing device 100 adds 1 to Npop in response to assigning the O2 atom to fragment F_3. Therefore, Npop becomes 4. Therefore, Npop≥the number of divisions is satisfied.

As a result, the information processing device 100 may assign atoms to each fragment F_n in a round robin manner, in descending order of the orbital count according to the above-mentioned policy. Therefore, the information processing device 100 may equalize the orbital count of atoms in each fragment F_n, and may easily reduce the amount of processing required when performing quantum chemical calculations.

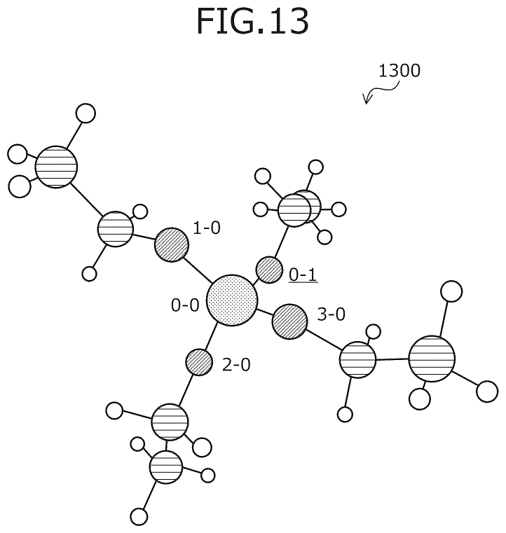

Furthermore, the information processing device 100 may first assign to fragment F_n, atoms that are located at coordinates close to each other according to the above-mentioned policy. Therefore, the information processing device 100 may assign atoms that belong to different branches on the structure 900 of the molecule-under-analysis to different fragments F_n, and may lengthen the diameter of each fragment F_n. The description will then shift to FIG. 13.

In FIG. 13, the information processing device 100 determines whether the extracted atomic group has become empty. In the example of FIG. 13, the information processing device 100 determines that the extracted atomic group “p2” [O3, C0, . . . , C7] is not empty.

When the extracted atomic group is not empty, the information processing device 100 determines whether Npop<division count is satisfied. Since Npop is 4, the information processing device 100 determines that Npop≥division count is satisfied. When Npop≥division count is satisfied, the information processing device 100 sets the atom most recently assigned to the fragment F_(Npop % division count) as the reference atom. In the example of FIG. 13, the information processing device 100 sets the Si atom most recently assigned to the fragment F_0 as the reference atom.

The information processing device 100 extracts the atom that is closest to the reference atom from the extracted atomic group “p2” [O3, C0, . . . , C7] based on the coordinates of the atom, and assigns the extracted atom to the fragment F_(Npop % division count).

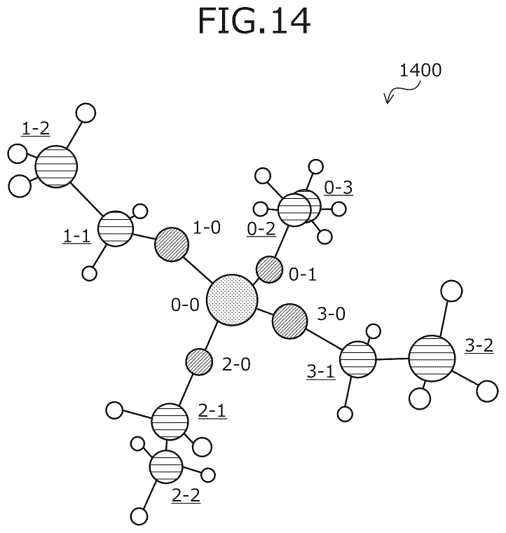

In the example of FIG. 13, as depicted in a pattern 1300, the information processing device 100 extracts the O3 atom that is closest to the Si atom and assigns the extracted O3 atom to the fragment F_0. Furthermore, the information processing device 100 adds 1 to Npop in response to assigning the O3 atom to the fragment F_0. Therefore, Npop becomes 5. The pattern 1300 indicates which atom is assigned to which fragment F_n in the process of assigning multiple atoms to multiple fragments F_n. The description will then shift to FIG. 14.

In FIG. 14, the information processing device 100 determines whether the extracted atomic group has become empty. In the example of FIG. 14, the information processing device 100 determines that the extracted atomic group “p2” [C0, . . . , C7] is not empty.

When the extracted atomic group is not empty, the information processing device 100 determines whether Npop<the number of divisions is satisfied. Since Npop is 5, the information processing device 100 determines that Npop is equal to or greater than the number of divisions. When Npop is equal to or greater than the number of divisions, the information processing device 100 sets the atom most recently assigned to the fragment F_(Npop % number of divisions) as the reference atom. In the example of FIG. 14, the information processing device 100 sets the O1 atom most recently assigned to the fragment F_1 as the reference atom.

Based on the coordinates of the atom, the information processing device 100 extracts the atom that is closest to the reference atom from the extracted atomic group “p2” [C0, . . . , C7] and assigns the extracted atom to the fragment F_(Npop % number of divisions).

In the example of FIG. 14, as depicted in a pattern 1400, the information processing device 100 extracts the C1 atom that is closest to the O1 atom and assigns the extracted C1 atom to the fragment F_1. Furthermore, the information processing device 100 adds 1 to Npop in response to the allocation of the C1 atom to the fragment F_1. Therefore, Npop becomes 6. The pattern 1400 indicates which atom has been allocated to which fragment F_n in the process of allocating multiple atoms to multiple fragments F_n.

The information processing device 100 repeats the series of processes in the same manner, in which a reference atom is set, an atom that is closest to the set reference atom among the extracted atomic group is extracted and the atom is allocated to the fragment F_(Npop % division count), until the extracted atomic group becomes empty. In this way, the information processing device 100 may assign each atom from the C1 atom to the C7 atom to each fragment F_n.

When the extracted atomic group becomes empty, the information processing device 100 newly extracts an atomic group with the maximum period in the periodic dictionary. By extracting an atomic group, the information processing device 100 deletes the atomic group from the periodic dictionary. The information processing device 100, for example, extracts the atomic group “p1” [H0, . . . , H19] from the periodic dictionary. Therefore, the periodic dictionary becomes empty.

The information processing device 100 repeats the series of processes, such as setting a reference atom, extracting an atom that is closest to the set reference atom from the extracted atomic group, and assigning the extracted atom to the fragment F_(Npop % division count), in the same manner, until the extracted atomic group becomes empty. In this way, the information processing device 100 may assign each atom from the H1 atom to the H19 atom to each fragment F_n.

In this way, the information processing device 100 may assign the atoms to each fragment F_n in a round robin manner in descending order of the orbital count according to the above-mentioned policy. Therefore, the information processing device 100 may equalize the orbital count of atoms in each fragment F_n, and may easily reduce the amount of processing required when performing quantum chemical calculations.

In addition, of the second or subsequent atoms to be assigned to the fragments F_n, the information processing device 100 may assign to a certain fragment F_n, atoms that are located at coordinates close to an atom that has been assigned to the certain fragment F_n, according to the above-mentioned policy. Therefore, the information processing device 100 may lengthen the diameter of each fragment F_n while assigning to the same fragment F_n, atoms that are located at coordinates close to each other in the structure 900 of the molecule-under-analysis.

In addition, the information processing device 100 may divide the structure 900 of the TEOS molecule into multiple fragments F_n by the number of divisions desired by the user, taking into consideration the trade-off between maintaining the accuracy of the quantum chemical calculation and reducing the amount of processing required when performing the quantum chemical calculation. As a result, the information processing device 100 may reduce the amount of processing required when performing the quantum chemical calculation while maintaining the accuracy of the quantum chemical calculation.

In addition, the information processing device 100 may easily equalize the orbital count of atoms in each fragment F_n, regardless of the structure of the molecule-under-analysis, depending on the positional relationship between the atoms, regardless of the connection relationship between the atoms. Thus, the information processing device 100 may reduce the amount of processing required when performing quantum chemical calculations.

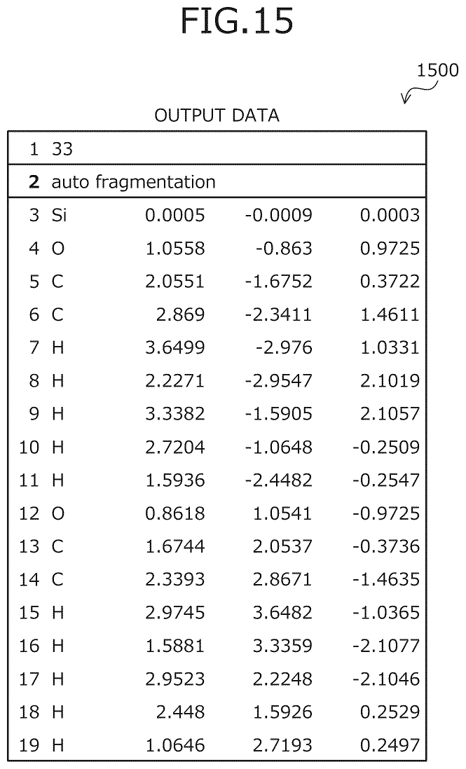

When the periodic dictionary becomes empty, the information processing device 100 determines that the division of the TEOS molecule structure 900 into multiple fragments F_n is completed. The information processing device 100 generates output data 1500, which will be described later in FIG. 15, depicting multiple fragments F_n. The information processing device 100 outputs the output data 1500 and the number of atoms of each fragment F_n. Next, moving to the description of FIG. 15, an example of the output data 1500 will be described.

FIG. 15 is an explanatory diagram depicting an example of the output data 1500. In FIG. 15, the left end of the output data 1500 is the line number.

The first line of the output data 1500 depicts that the number of atoms of the TEOS molecule is 33. The second line of the output data 1500 is a comment field. The third and subsequent lines of the output data 1500 indicate the type of atom and the coordinates of the atom sorted for each fragment F_n. The type is, for example, Si, O, C, or H. The coordinates are a combination of x, y, and z coordinate values in a three-dimensional space.

For example, the third to eleventh lines of the output data 1500 correspond to the fragment F_0. The delimiter of the line range corresponding to the fragment F_n in the output data 1500 can be determined based on, for example, a change in the orbital count between lines. The information processing device 100 may store, for example, the delimiter of the line range corresponding to the fragment F_n in the output data 1500.

The information processing device 100 may perform a quantum chemical calculation using DMET based on the output data 1500. The information processing device 100 may control, for example, the chemical calculation device 201 to perform a quantum chemical calculation using DMET. The information processing device 100 outputs the result of performing the quantum chemical calculation using DMET. As a result, the information processing device 100 may perform the quantum chemical calculation using DMET with high accuracy and efficiency. The information processing device 100 may make the result of performing the quantum chemical calculation using DMET available.

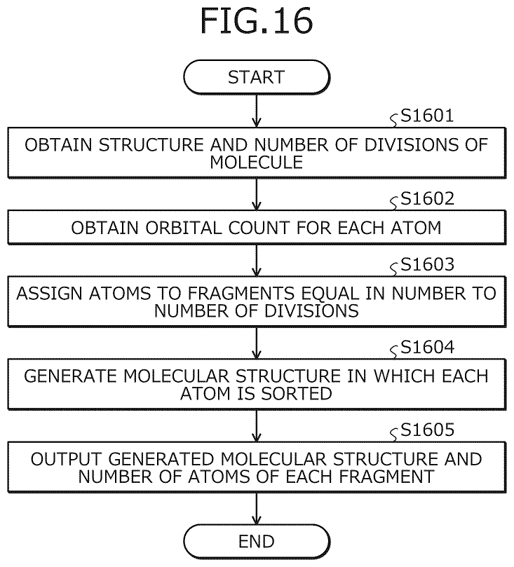

An example of the overall processing procedure executed by the information processing device 100 will then be described with reference to FIG. 16. The overall processing is an example of the operation of the information processing device 100 shown in, for example, FIGS. 7 to 14. The overall processing is implemented by, for example, the CPU 301 depicted in FIG. 3, a storage area such as the memory 302 and the recording medium 305, and the network I/F 303.

FIG. 16 is a flowchart depicting an example of the overall processing procedure. In FIG. 16, the information processing device 100 obtains the structure and the number of divisions of the molecule (step S1601). Next, the information processing device 100 obtains the orbital count of each of the multiple atoms forming the molecule by referring to the periodic table (step S1602).

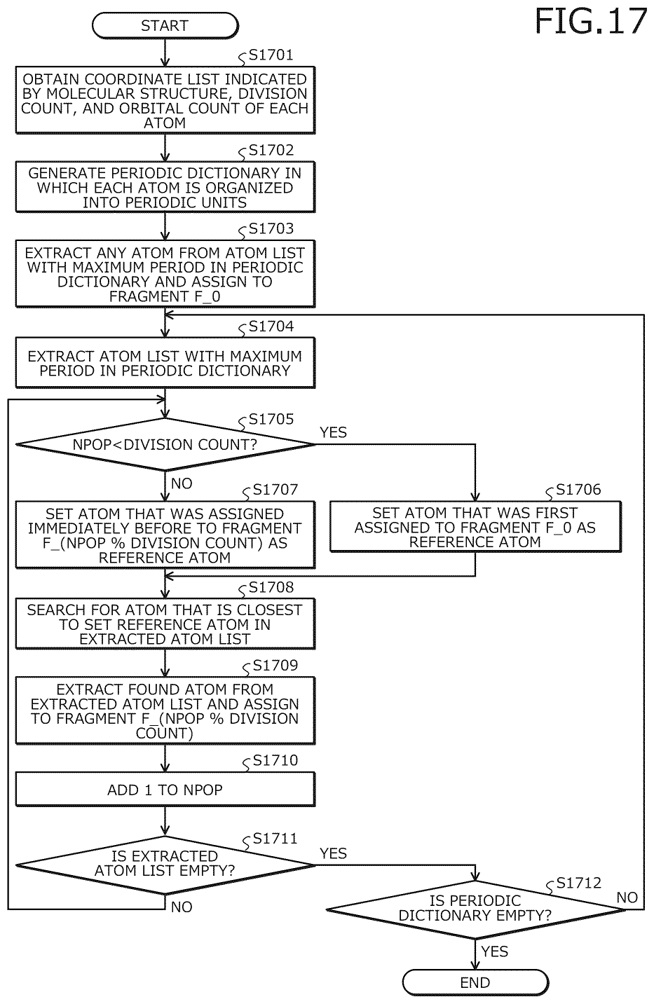

Then, the information processing device 100 assigns, respectively, atoms to fragments of a count equal to the number of divisions based on the molecular structure, the number of divisions, and the orbital count of each atom (step S1603). For example, the information processing device 100 assigns, respectively, the atoms to fragments of a count equal to the number of divisions by executing an assignment process described later with reference to FIG. 17.

The information processing device 100 then generates a molecular structure in which each atom is sorted based on the multiple fragments (step S1604). Then, the information processing device 100 outputs the generated molecular structure and the number of atoms of each fragment (step S1605). Thereafter, the information processing device 100 ends the entire process.

An example of an assignment processing procedure executed by the information processing device 100 will then be described with reference to FIG. 17. The assignment process is implemented by, for example, the CPU 301, the memory 302, the recording medium 305, and the network I/F 303 depicted in FIG. 3.

FIG. 17 is a flowchart depicting an example of the assignment process procedure. In FIG. 17, the information processing device 100 obtains a coordinate list indicated by the molecular structure, the division count, and the orbital count of each atom (step S1701).

The information processing device 100 then generates a periodic dictionary in which each atom is organized into periodic units based on the orbital count of the atom (step S1702). Then, the information processing device 100 extracts from the atom list, an atom with the maximum period in the periodic dictionary and assigns the extracted atom to the fragment F_0 (step S1703).

The information processing device 100 then extracts the atom list having the maximum period in the periodic dictionary (step S1704). Then, the information processing device 100 determines whether Npop<the division count is satisfied (step S1705). Here, when Npop<division count is satisfied (step S1705: YES), the information processing device 100 proceeds to processing at step S1706. On the other hand, when Npop is not<division count but Npop≥division count (step S1705: NO), the information processing device 100 proceeds to processing at step S1707.

At step S1706, the information processing device 100 sets the atom that was first assigned to the fragment F_0 as the reference atom (step S1706). Then, the information processing device 100 proceeds to processing at step S1708.

At step S1707, the information processing device 100 sets the atom that was assigned immediately before to the fragment F_(Npop % division count) as the reference atom (step S1707). Then, the information processing device 100 proceeds to processing at step S1708.

At step S1708, the information processing device 100 searches for an atom that is closest to the set reference atom in the extracted atom list (step S1708). Then, the information processing device 100 extracts the found atom from the extracted atom list and assigns the extracted atom to the fragment F_(Npop % division count) (step S1709).

The information processing device 100 then adds 1 to Npop (step S1710). Then, the information processing device 100 determines whether the extracted atom list is empty (step S1711). Here, when the atom list is not empty (step S1711: NO), the information processing device 100 returns to the process at step S1705. On the other hand, when the atom list is empty (step S1711: YES), the information processing device 100 proceeds to the process at step S1712.

At step S1712, the information processing device 100 determines whether the periodic dictionary is empty (step S1712). Here, when the periodic dictionary is not empty (step S1712: NO), the information processing device 100 returns to the process at step S1704. On the other hand, when the periodic dictionary is empty (step S1712: YES), the information processing device 100 ends the assignment process.

Here, the information processing device 100 may switch the order in which some of the steps of the processes depicted in the flowcharts of FIG. 16 and FIG. 17 are performed. For example, the order of the process of steps S1601 and S1602 may be interchanged. In addition, the information processing device 100 may omit some steps of the process of the flowcharts in FIGS. 16 and 17.

The information processing device 100 may be applied to, for example, fields such as drug development or material development. For example, the information processing device 100 may be applied to cases where it is desired to perform quantum chemical calculations to calculate the ground-state energy of a molecule in order to analyze the structure or properties of a molecule that is a candidate for a drug or material in fields such as drug development or material development. As a result, the information processing device 100 may reduce the amount of processing required when performing quantum chemical calculations while maintaining the accuracy of the quantum chemical calculations, making it easier to calculate the ground-state energy of a molecule, and may contribute to fields such as drug development or material development.

As set forth hereinabove, the information processing device 100 may obtain the fragment count into which the structure of a molecule-under-analysis containing multiple atoms is divided, information specifying the orbital count of each of the multiple atoms, and the coordinates of each atom. The information processing device 100 may assign the multiple atoms to two or more fragments based on the obtained information and the obtained coordinates. The information processing device 100 may assign among the multiple atoms, for example, each of two or more atoms (the number of which is equal to the obtained fragment count 101) in descending order of the orbital count 102, respectively, to each of two or more fragments 110 (the number of which is equal to the obtained fragment count 101). According to the information processing device 100, for example, among the remaining atoms exclusive of the two or more atoms, atoms close to other atoms that have already been assigned to the respective fragments may be assigned to the fragments. According to the information processing device 100, two or more fragments to which multiple atoms have been assigned may be output. In this way, the information processing device 100 may divide the structure of the molecule-under-analysis into two or more fragments so as to reduce the amount of processing required when performing the quantum chemical calculation while maintaining the accuracy of the quantum chemical calculation.

According to the information processing device 100, any first fragment of two or more fragments may be selected. According to the information processing device 100, any first atom of one or more first atoms having the largest orbital count among the multiple atoms may be extracted and assigned to the selected first fragment. According to the information processing device 100, each second fragment of the remaining second fragments exclusive of the selected first fragment among the two or more fragments may be selected sequentially, once each. According to the information processing device 100, any second atom close to any of the first atoms of one or more second atoms having the largest orbital count among the multiple atoms may be extracted and assigned to the selected second fragments. Thereby, the information processing device 100 may properly assign each of the two or more atoms, the number of which is equal to the fragment count, respectively, to each of the two or more fragments, the number of which is equal to the fragment count, in descending order of the orbital count.

According to the information processing device 100, each fragment of the two or more fragments may be recursively selected sequentially. According to the information processing device 100, among one or more third atoms having the largest orbital count among the remaining atoms, any third atom close to the atom assigned to the selected fragment immediately before may be extracted and assigned to the selected fragment. Thereby, the information processing device 100 may suitably assign, among the remaining atoms exclusive of the two or more atoms, an atom close to other atoms already assigned to a given fragment to the given fragment.

According to the information processing device 100, information indicating each atom of the one or more atoms assigned to fragments may be output in association with information indicating each fragment of the two or more fragments. Thereby, the information processing device 100 may make available various types of information that enables quantum chemical calculation to be performed.

According to the information processing device 100, it is possible to perform quantum chemical calculations according to DMET, based on two or more fragments into which multiple atoms are assigned. As a result, the information processing device 100 may perform quantum chemical calculations efficiently and accurately. The information processing device 100 can make the results of the quantum chemical calculations available.

The information processing method described in the present embodiment may be implemented by executing a prepared program on a computer such as a personal computer and a workstation. The program is stored on a non-transitory, computer-readable recording medium such as a hard disk, a flexible disk, a compact disc read-only memory (CD-ROM), a magneto-optical (MO) disc, and a digital versatile disc (DVD), read out from the computer-readable medium, and executed by the computer. The program may be distributed through a network such as the Internet.

According to one aspect, it is possible to easily reduce the amount of processing.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A recording medium storing therein an information processing program for causing a computer to execute a process comprising:
obtaining a fragment count by which a structure of a molecule-under-analysis containing a plurality of atoms is divided, information specifying an orbital count of each of the plurality of atoms, and coordinates of each of the plurality of atoms;
based on the obtained information and the obtained coordinates, executing:
as a first process, assigning among the plurality of atoms, two or more atoms, a number thereof being equal to the obtained fragment count, the two or more atoms being assigned in descending order of the orbital count, respectively, to two or more fragments, a number thereof being equal to the obtained fragment count;
as a second process, assigning, with respect to each of the two or more fragments, an atom that of remaining atoms exclusive of the two or more atoms among the plurality of atoms, is close in distance to another atom already
assigned to the each of the two or more fragments;
assigning the plurality of atoms to the two or more fragments; and
outputting the two or more fragments to which the plurality of atoms are assigned.

2. The recording medium according to claim 1, wherein
the plurality of atoms includes one or more first atoms having a first orbital count that is largest among the plurality of atoms, and one or more second atoms having a second orbital count that is largest among the plurality of atoms exclusive of the one or more first atoms,
the first process includes:
selecting, as a first fragment, one of the two or more fragments and assigning any of the one or more first atoms to the selected first fragment; and
sequentially selecting, once, each of second fragments that remain among the two or more fragments exclusive of the selected first fragment and assigning to the selected each of second fragments, any second atom close in distance to the any of the one or more first atoms, among the one or more second atoms.

3. The recording medium according to claim 2, wherein
the plurality of atoms includes one or more third atoms having a third orbital count largest among the remaining atoms exclusive of the one or more first atoms and the one or more second atoms, and
the second process includes recursively selecting each of the two or more fragments sequentially and assigning to the selected fragment, any third atom close in distance to an atom most recently assigned to the selected each of the two or more fragments.

4. The recording medium according to claim 1, wherein
the outputting includes outputting, in association with information indicating each of the two or more fragments, information indicating each of one or more atoms assigned to the each of the two or more fragments.

5. The recording medium according to claim 1, the process further comprising
performing a quantum chemical calculation according to density matrix embedding theory, based on the two or more fragments to which the plurality of atoms are assigned.

6. An information processing method executed by a computer, the information processing method comprising:
obtaining a fragment count by which a structure of a molecule-under-analysis containing a plurality of atoms is divided, information specifying an orbital count of each of the plurality of atoms, and coordinates of each of the plurality of atoms;
based on the obtained information and the obtained coordinates, executing:
as a first process, assigning among the plurality of atoms, two or more atoms, a number thereof being equal to the obtained fragment count, the two or more atoms being assigned in descending order of the orbital count, respectively, to two or more fragments, a number thereof being equal to the obtained fragment count;
as a second process, assigning, with respect to each of the two or more fragments, an atom that of remaining atoms exclusive of the two or more atoms among the plurality of atoms, is close in distance to another atom already assigned to the each of the two or more fragments;
assigning the plurality of atoms to the two or more fragments; and
outputting the two or more fragments to which the plurality of atoms are assigned.

7. An information processing device, comprising:
a memory; and
a processor coupled to the memory, the processor configured to:
obtain a fragment count by which a structure of a molecule-under-analysis containing a plurality of atoms is divided, information specifying an orbital count of each of the plurality of atoms, and coordinates of each of the plurality of atoms;
based on the obtained information and the obtained coordinates, execute:
as a first process, assigning among the plurality of atoms, two or more atoms, a number thereof being equal to the obtained fragment count, the two or more atoms being assigned in descending order of the orbital count, respectively, to two or more fragments, a number thereof being equal to the obtained fragment count;
as a second process, assigning, with respect to each of the two or more fragments, an atom that of remaining atoms exclusive of the two or more atoms among the plurality of atoms, is close in distance to another atom already assigned to the each of the two or more fragments;
assigning the plurality of atoms to the two or more fragments; and
outputting the two or more fragments to which the plurality of atoms are assigned.
